(19) United States
(12) Patent Application Publication
(10) Pub. No.: US 2024/0114666 A1
(43) Pub. Date: Apr. 4, 2024

(54) HEAT SINK FOR COMPUTE BLADE NETWORK CARD

(71) Applicants: BULL SAS, Les Clayes-sous-Bois (FR); Le Commissariat à l’énergie atomique et aux énergies alternatives (CEA), Paris (FR)

(72) Inventors: Pierre LAMY, Paris (FR); Sébastien MAGNOUX, Mery-sur-Oise (FR)

(73) Assignees: BULL SAS, Les Clayes-sous-Bois (FR); Le Commissariat à l’énergie atomique et aux énergies alternatives (CEA), Paris (FR)

(21) Appl. No.: 18/469,829

(22) Filed: Sep. 19, 2023

(30) Foreign Application Priority Data
Sep. 28, 2022 (EP) 22306439.5

(51) Int. Cl. H05K 7/20

(52) U.S. Cl. CPC H05K 7/20772; H05K 7/20254; H05K 7/2039

(57) ABSTRACT

Heat sink for a network card of a compute blade, said compute blade comprising a cold plate wherein a cooling liquid circulates, said heat sink comprising a body comprising two main faces of which a so-called “hot” face and a so-called “cold” face, opposite said hot face, said cold face being configured to be interfaced with the cold plate, the hot face comprising at least one housing configured to receive at least one heat generating component of the network card.

This application claims priority to European Patent Application Number 22306439.5, filed 28 Sep. 2022, the specification of which is hereby incorporated herein by reference.

### BACKGROUND OF THE INVENTION

### Technical Field of the Invention

At least one embodiment of the invention relates to the field of cooling the network cards of a supercomputer compute blade and relates more particularly to a heat sink for a compute blade network card and a conduction cooled heat dissipation module for a compute blade as well as their methods for manufacturing.

### Description of the Related Art

In server compute blades, particularly for supercomputers, it is known to use high speed network cards, particularly mezzanine cards for high speed links, called OCP 3.0 cards, to enable communication between the compute blades and the use of the power of several processors for the execution of the same task.

The current cooling solutions for these OCP 3.0 cards use the principle of air cooling. In other words, the components are cooled by air radiators interfaced on the network card.

Existing network cards have the disadvantage of not being compatible with liquid cooling systems without forced convection, wherein the coolant circulates in a cold plate.

Indeed, each network card does not comprise its components and connectors in the same locations, which makes it complex or even impossible in some cases to interface the network card directly on a cold plate without having to machine it. Thus, the cold plate should be changed as soon as a component or connector is added or of different dimensions on the network card.

It would therefore be advantageous to propose a simple, reliable and effective solution to at least partially remedy these disadvantages.

### BRIEF SUMMARY OF THE INVENTION

At least one embodiment of the invention is to propose a simple, reliable and effective solution for heat dissipation for network cards, in particular OCP 3.0 cards.

To this end, at least one embodiment of the invention has for object a heat sink for a compute blade network card, the compute blade including a cold plate wherein a cooling liquid circulates, the heat sink including a body that includes two main faces of which a so-called “hot” face and a so-called “cold” face, opposite the hot face, the cold face being configured to be interfaced with the cold plate, the hot face including at least one housing configured to receive at least one heat generating component of the network card.

The term “interfaced” means that the cold face is shaped to come into contact with the cold plate, preferably over the entire surface of said cold face, in order to transmit its heat effectively to it. The heat generating component(s) may be electronic components, for example of the chip or microprocessor or capacitor type, or electrical components, for example of the connector type.

By allowing the network card to follow its shape, the heat sink according to one or more embodiments of the invention has an improved compactness making it possible to minimize the space occupied in the compute blade. In addition, the heat sink according to one or more embodiments of the invention may be adapted to any type of network card, in particular for mounting a card in OCP 3.0 format, by being declinable to the different sub-formats SFF, TSFF, LFF of the OCP 3.0 standard. In addition, the heat sink according to at least one embodiment of the invention is compatible for compute blades without forced air circulation, in particular for liquid-cooled compute blades. In particular, the heat sink according to one or more embodiments of the invention is compatible with most existing types of cold plate.

Preferably, in at least one embodiment, the heat sink comprises a heat conduction interface mounted on the cold face of the body in order to improve the collection of the heat generated by the components of the network card and the transfer of the heat by the body, by conduction, to the cold plate.

Advantageously, in at least one embodiment, the heat conduction interface is in the form of a heat conducting plate, preferably made of a flexible heat conducting material such as, for example, a conductive thermal paste or a conductive, especially shape memory, thermal foam.

Preferably, in one or more embodiments, the heat sink comprises a housing element for covering the network card to protect it.

In at least one embodiment, the housing element comprises a protective plate configured to cover at least partially the network card, preferably at least 90% of its surface.

Preferably, in one or more embodiments, the protective plate is made of steel for its resistance and its strength.

Advantageously, in at least one embodiment, the housing element comprises a connection front, fastened to the protective plate, comprising a portion extending orthogonally to the protective plate and delimiting at least one receiving hole of a connector of the network card in order to facilitate the mounting and connection of the network card in the compute blade.

According to at least one embodiment of the invention, the body delimits, at the cold face, a plurality of fasteners each configured to receive a screw making it possible to fasten the body on the cold plate.

According to at least one embodiment of the invention, the body delimits a plurality of through-fastening holes, connecting the hot face to the cold face, each configured to receive an assembly screw making it possible to firmly secure both the body and the network card.

Using two different assemblies of fastening holes to fasten the network card to the body and to fasten the body to the cold plate makes it possible to mount the network card on the body independently of the mounting of the heat sink on the cold plate.

In at least one embodiment, the heat sink comprising a housing element, said housing element delimits a plurality of through-fastening holes, aligned with the through-fastening holes of the body, each configured to receive an assembly screw making it possible to firmly secure the housing element, the body, and the network card.

Advantageously, in one or more embodiments, the body is made of metal, preferably aluminum, more preferably in series (or grade) 6063 aluminum in order to ensure the necessary cooling performance.

At least one embodiment of the invention also relates to a heat dissipation module comprising a network card mounted on the body of a heat sink as presented previously.

The heat dissipation module according to one or more embodiments of the invention has an improved compactness making it possible to minimize the space occupied in the compute blade and is compatible with most existing types of cold plate.

The network card is an electronic card configured to allow communication between the compute blade motherboard and at least one other compute blade or a server, in particular to allow the use of the power of several processors for the execution of the same task, by way of one or more embodiments.

Preferably, in at least one embodiment, the network card is of the OCP 3.0 type.

As the heat dissipation module comprises the network card mounted on the body, it may be assembled, preferably in the chain, independently in a first step, before being mounted on the cold plate in a second step, by way of one or more embodiments.

In at least one embodiment, the heat sink comprising a housing element of the network card on the body, said housing element is at least integral with the network card, preferably both with the network card and the body, the network card is mounted between the housing element and the body. The housing element makes it possible to protect the side of the network card that is opposite the side facing the hot face of the body of the heat sink.

In at least one embodiment, the housing element is fastened by means of screws, preferably by means of two-part assembly screws which are effective for firmly securing elements, in particular metal plate types, together.

At least one embodiment of the invention also relates to a compute blade for a supercomputer, said compute blade comprising a cold plate, through which a liquid cooling circuit runs, and a heat dissipation module such as presented above, of which the body of the heat sink is fastened on the cold plate via its cold face.

At least one embodiment of the invention also relates to a method for manufacturing a heat sink for a compute blade network card, said method comprising creating, preferably by machining, a body comprising a “hot” face and a “cold” face, opposite said hot face, said cold face being configured to be interfaced with the cold plate, the hot face comprising at least one housing configured to receive at least one heat generating component of the network card.

In at least one embodiment, the method further comprises creating a housing element configured to be fastened to the body in order to protect the network card arranged between said housing element and said body.

At least one embodiment of the invention also relates to a method for assembling a heat dissipation module, said method comprising mounting a network card on the body of a heat sink such as presented above, the network card comprising an upper face comprising at least one heat generating component and a lower face, opposite said upper face, the mounting being performed so that the upper face of the network card is mounted opposite the hot face of the body of the heat sink, the at least one component extending into the at least one housing of the hot face.

In at least one embodiment, the assembly comprises firmly securing the network card on the body by means of fastening screws.

In at least one embodiment, the method comprises placing a housing element on the network card so as to protect the lower face of the network card.

Preferably, in one or more embodiments, the mounting comprises firmly securing the housing element, the network card and the body by means of fastening screws. Alternatively, in at least one embodiment, the housing element could be fastened only on the lower face of the network card.

At least one embodiment of the invention also relates to a method for assembling a compute blade, as described above, for supercomputer, said method comprising fastening a heat dissipation module as described above on the cold plate of the compute blade.

### BRIEF DESCRIPTION OF THE DRAWINGS

Further characteristics and advantages of the one or more embodiments of the invention will further appear upon reading the description that follows. This is purely illustrative and should be read in conjunction with the appended drawings in which:

FIG. 1 schematically shows a heat dissipation module according to one or more embodiments of the invention in an exploded view from above.

FIG. 2 schematically shows the heat dissipation module of FIG. 1 in assembled view, according to one or more embodiments of the invention.

FIG. 3 schematically shows the heat dissipation module of FIG. 1 in an exploded view from below, according to one or more embodiments of the invention.

FIG. 4 schematically shows the heat dissipation module of FIG. 3 in assembled view, according to one or more embodiments of the invention.

FIG. 5 schematically shows a method for manufacturing according to one or more embodiments of the invention.

### DETAILED DESCRIPTION OF THE INVENTION

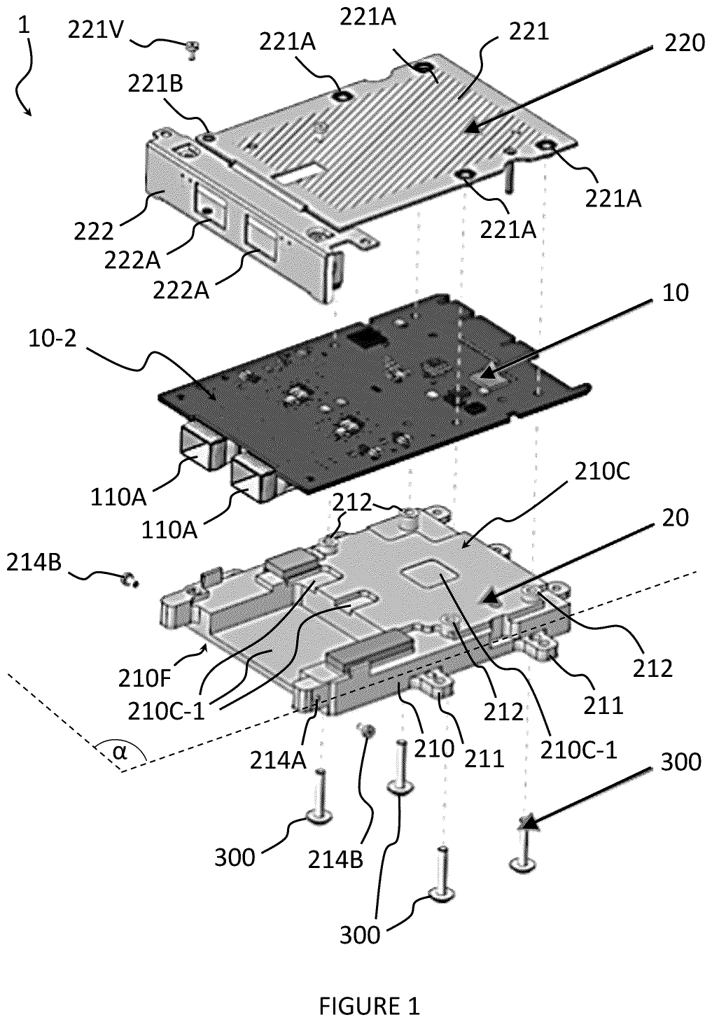

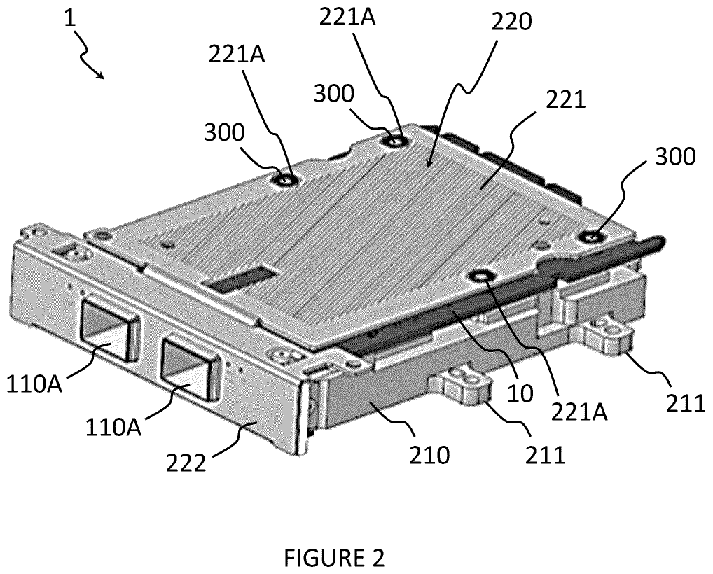

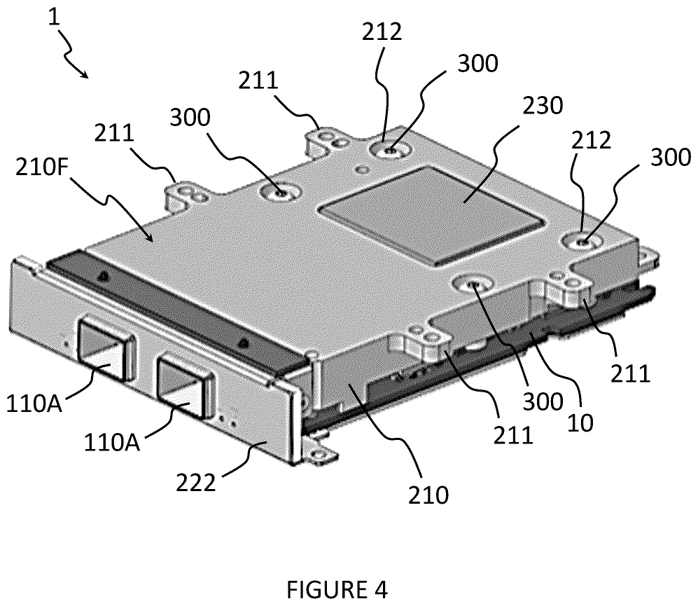

FIGS. 1 to 4 show different views of an example heat dissipation module 1 according to one or more embodiments of the invention (exploded and assembled top and bottom views).

The heat dissipation module 1 according to at least one embodiment of the invention is configured to be mounted on a cold plate of a supercomputer compute blade (not shown).

Compute Blade

The compute blade is intended to be mounted in a computer bay of a supercomputer.

The compute blade comprises a motherboard configured to perform computer processing of tasks, in particular computing tasks and communication tasks with other compute blades or servers via one or more communication networks, according to one or more embodiments of the invention. To this end, the compute blade comprises one or more network cards provided in as many heat dissipation modules according to at least one embodiment of the invention.

The compute blade also comprises a cold plate through which a liquid cooling circuit runs, according to one or more embodiments of the invention. The liquid cooling circuit allows cooling liquid, for example water, to be routed through the cold plate in order to cool various compute blade components such as, for example, the processors of the motherboard or the heat generating components of the network card(s), via heat sinks.

The cold plate in particular comprises a surface adapted to receive a heat dissipation module 1 according to at least one embodiment of the invention, preferably a flat surface to improve thermal conduction between said heat dissipation module 1 and said cold plate.

Heat Dissipation Module 1

Each heat dissipation module 1 comprises a network card 10 and a heat sink 20 according to one or more embodiments of the invention.

The heat dissipation module 1 is intended to be mounted on the cold plate of the compute blade in order to cool the network card 10 by collecting the heat generated by the electrical 110A or electronic 110B components of said network card 10, according to one or more embodiments of the invention.

Network Card 10

The network card 10 is configured to allow communication between the motherboard of the compute blade wherein it is mounted and one or more other compute blades or servers, in particular to allow the use of the power of several processors for the execution of the same task, according to one or more embodiments of the invention.

Each network card 10 comprises electrical components 110A and/or electronic components 110B, these components 110A, 110B generating or capable of generating heat during operation of said network card 10.

In the example described with respect to the figures, in at least one embodiment, the network card 10 comprises two electrical components in the form of connectors 110A making it possible to electrically connect said network card 10 on the one hand to the compute blade motherboard and on the other hand to an external communication link or network, for example via a switch.

Still in the example described with respect to the figures, according to one or more embodiments of the invention, the network card 10 comprises several electronic components 110B. These electronic components 110B may in particular be microprocessors, chips or capacitors or any other element generating heat in operation of said network card 10.

The network card 10 is in the form of an electronic circuit comprising an upper face 10-1 on which the various electrical and electronic components 110A, 110B and a lower face 10-2, mainly comprising the electrical paths and welds of the component legs 110A, 110B, are mounted.

Heat Sink 20

The heat sink 20 is of the conduction cooled type and for this purpose comprises, as shown in FIGS. 1 to 4, a body 210 which is adapted both to collect heat from the network card 10 and to be fastened to the cold plate of the compute blade, wherein the cooling liquid circulates, in order to discharge said heat by conduction to said cooling circuit, according to one or more embodiments of the invention.

In the example shown in the figures, in at least one embodiment, the heat sink 20 further comprises a housing element 220 for protecting the network card 10, as shall be described hereinafter.

Body 210

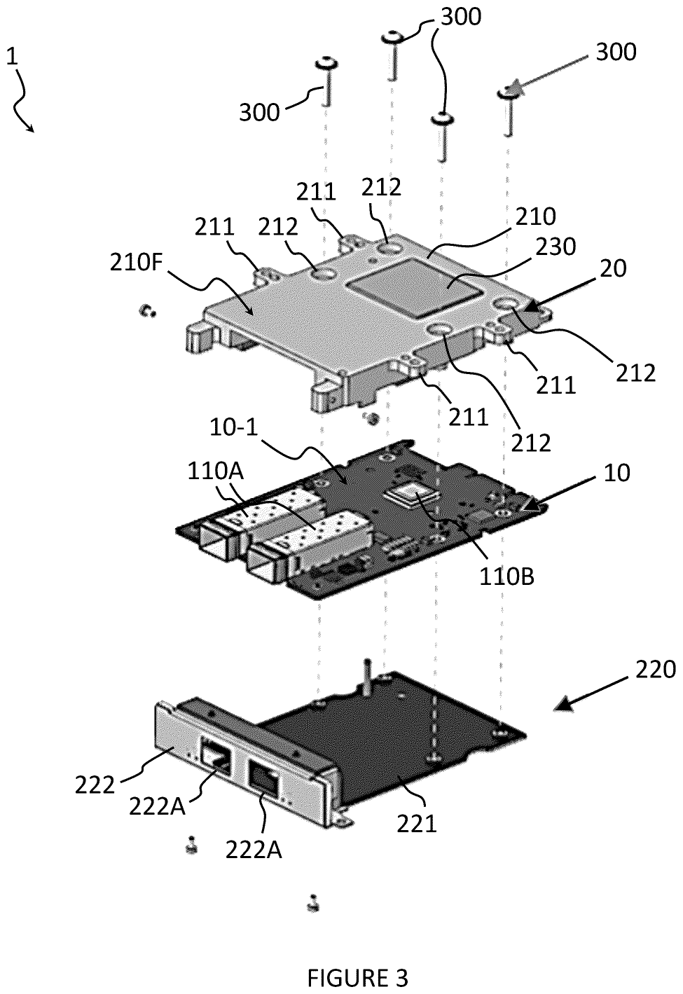

In reference to FIGS. 1 and 3, according to one or more embodiments of the invention, the body 210 extends into a main plane a and comprises two main faces: a “hot” face 210C (FIG. 1) and a “cold” face 210F (FIG. 3), opposite said hot face 210C.

The body 210 is made of metal, preferably aluminum, more preferably series 6063 aluminum.

The cold face 210F of the body 210 is configured to interface with the cold plate. The term “to interface” is understood to mean that the cold face 210F of the body 210 is placed against the cold plate to transfer, by conduction, the heat collected by the hot face 210C of said body 210.

The cold face 210F advantageously has, in the example shown in the figures, a substantially flat surface on which is mounted a heat conduction interface 230, visible in FIG. 3, in order to improve the conduction of heat to the cold plate.

The heat conduction interface 230 is in the form of a flat metal heat-conducting portion, for example made of aluminum, preferably series 6063. A conductive flexible material used to transmit heat between the cold plate and the heat conduction interface 230 of the network card may be used, for example a conductive shape memory paste or foam.

The hot face 210C is intended to receive the upper face 10-1 of the network card 10 to collect the heat generated by the components 110A, 110B of said network card 10, according to one or more embodiments of the invention. For this purpose, in reference to FIG. 1, in at least one embodiment, the hot face 210C comprises housings 210C-1 configured to receive the connectors 110A and the heat generating electronic components 110B of the network card 10.

The hot face 210C is configured so that the components 110A, 110B may come into contact with one or more walls of the housings 210C-1 and/or be positioned at a small distance from the walls of the housings 210C-1, for example less than 5 mm, to absorb the heat generated by said components 110A, 110B.

In the example shown in the figures, according to one or more embodiments of the invention, the body 210 delimits four fasteners 211, derived from material of the body 210, configured to enable the body 210 to be fastened to the cold plate using screws (not shown).

The body 210 also delimits four through-fastening holes 212 connecting the cold face 210F to the hot face 210C and configured to each receive an assembly screw 300 making it possible to fasten the network card 10 onto said body 210.

The body 210 also delimits two side holes 214A for receiving two single fastening screws 214B of the housing element 220.

Housing Element 220

The housing element 220 comprises a protective plate 221 and a connection front 222, according to one or more embodiments of the invention.

The rectangular protective plate 221 is configured to cover the lower face 10-2 of the network card 10 to protect it. The protective plate 221 may, for example, be in the form of a sheet. The protective plate 221 may be made of steel, for example.

The protective plate 221 delimits four through-fastening holes 221A for receiving the assembly screws 300 that pass through the protective plate 221, the network card 10, and the body 210 in this example to firmly secure them together. The protective plate 221 also delimits a hole 221B for receiving a screw 221V for fastening the protective plate 221 on the network card 10.

In this example, according to one or more embodiments of the invention, the connection front 222 is in the form of an L-profile fastened on the protective plate 221, for example by welding or clipping.

The connection front 222 delimits two rectangular 222A openings making it possible to receive the two connectors 110A of the network card 10.

### Example of Manufacturing

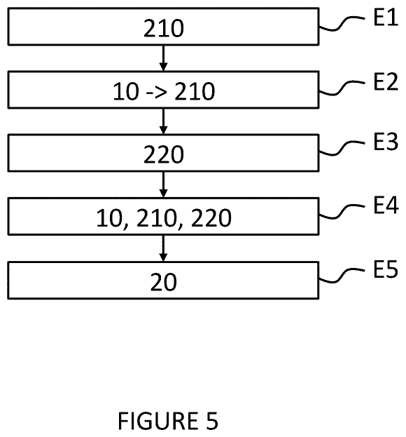

In reference to FIG. 5, according to one or more embodiments of the invention, the body 210 of the heat sink 20 is manufactured in a first step E1. The manufacturing of the heat sink 20 comprises the creation of the body 210, for example by machining in series 6063 aluminum, in particular the hot face 210C and the cold face 210F so as to form the housings 210C-1 for receiving the heat generating components 110A, 110B of the network card 10.

Then, in a step E2, the network card 10 is placed on the body 210 so that the upper face 10-1 of said network card 10 is mounted opposite the hot face 210C of the body 210 of the heat sink 20, the components 110A, 110B extending into their respective housings 210C-1 of the hot face 210C.

In a step E3, in at least one embodiment, the housing element 220, in particular the protective plate 221, is placed on the lower face 10-2 of the network card 10 so as to cover it and so that the connectors 110A of the network card 10 extend through the openings 222A of the connection front 222.

The housing element 220, the network card 10 and the body 210 are then firmly secured in a step E4, in particular using the assembly screws 300.

In a step E5, in at least one embodiment, the heat sink 20 thus assembled may then be mounted on the cold plate of the compute blade using screws and fasteners 211 so that the cold face 210F is interfaced with a portion of the cold plate.

The at least one embodiment of the invention thus has the advantage of being able to interface a single heat sink with more than four or five connectors, in particular with sixteen connectors, while maintaining significant compactness, efficiency and robustness.

1. A heat sink for a network card of a compute blade, said compute blade comprising a cold plate wherein a cooling liquid circulates, said heat sink comprising:
a body comprising two main faces, wherein said two main faces comprise
a hot face, and
a cold face, opposite said hot face,
wherein said cold face is configured to be interfaced with the cold plate, and
wherein the hot face comprises at least one housing configured to receive at least one heat generating component of the network card.

2. The heat sink according to claim 1, further comprising a heat conduction interface mounted on the cold face of the body.

3. The heat sink according to claim 2, wherein the heat conduction interface is in a form of a heat conducting plate.

4. The heat sink according to claim 1, wherein said heat sink further comprises a housing element configured to cover the network card.

5. The heat sink according to claim 4, wherein the housing element comprises a protective plate configured to cover the network card.

6. The heat sink according to claim 5, wherein the protective plate is made of steel.

7. The heat sink according to claim 5, wherein the housing element further comprises a connection front, fastened to the protective plate, comprising a portion extending orthogonally to the protective plate and delimiting at least one receiving hole of a connector of the network card.

8. The heat sink according to claim 1, wherein the body delimits, at the cold face, a plurality of fasteners each configured to receive a screw making it possible to fasten the body on the cold plate.

9. The heat sink according to claim 1, wherein the body delimits a plurality of through-fastening holes, connecting the hot face to the cold face, each configured to receive an assembly screw making it possible to firmly secure both the body and the network card.

10. The heat according to claim 9, wherein said heat sink further comprises a housing element, wherein said housing element delimits a plurality of through-fastening holes, aligned with the through-fastening holes of the body, each configured to receive an assembly screw making it possible to firmly secure the housing element, the body and the network card.

11. A heat dissipation module comprising:
a network card mounted on a body of a heat sink,
wherein said network card is a network card of a compute blade, said compute blade comprising a cold plate wherein a cooling liquid circulates,
wherein said heat sink comprises
said body comprising two main faces, wherein said two main faces comprise
a hot face, and
a cold face, opposite said hot face,
wherein said cold face is configured to be interfaced with the cold plate, and
wherein the hot face comprises at least one housing configured to receive at least one heat generating component of the network card.

12. The heat dissipation module according to claim 11, wherein the heat sink further comprises a housing element firmly secured at least with the network card, wherein the network card is mounted between the housing element and the body.

13. The heat dissipation module according to claim 11, wherein the body of said heat sink is fastened on the cold plate via its cold face.

14. A method for manufacturing a heat sink for a compute blade network card, said compute blade comprising a cold plate wherein a cooling liquid circulates, said method comprising:
creating a body comprising two main faces, wherein said two main faces comprise
a hot face, and
a cold face, opposite said hot face,
wherein said cold face is configured to be interfaced with the cold plate,
wherein the hot face comprises at least one housing configured to receive at least one heat generating component of the network card.

15. The heat dissipation module according to claim 11, wherein the network card comprises an upper face comprising at least one heat generating component and a lower face, opposite said upper face, wherein said heat dissipation module is assembled such that the upper face of the network card is mounted opposite the hot face of the body of the heat sink, with the at least one component extending into the at least one housing of the hot face.
